(19) United States
(12) Patent Application Publication
(10) Pub. No.: US 2002/0004273 A1
(43) Pub. Date: Jan. 10, 2002

(54) IMPROVED PROCESS FOR FORMING A STORAGE ELECTRODE

(76) Inventor: KAZUTAKA MANABE, TOKYO (JP)

Correspondence Address: HUTCHINS, WHEELER & DITTMAR, 101 FEDERAL STREET, BOSTON, MA, 02110, US

(21) Appl. No.: 09/221,074

(22) Filed: Dec. 28, 1998

(30) Foreign Application Priority Data
Dec. 26, 1997 (JP) 9-360272

(51) Int. Cl. H01L 21/8242

(52) U.S. Cl. 438/254; 438/255

(57) ABSTRACT

In a process for forming a storage electrode having a number of hemi-spherical grains formed on a surface thereof, after a number of hemi-spherical grains are formed on a surface of the storage electrode, phosphorus or arsenic is ion-implanted to the hemi-spherical grains under an ion implantation energy of 20 keV to 50 keV.

### BACKGROUND OF THE INVENTION

1. Field of the Invention

The present invention relates to a process for forming a storage electrode, and more specifically to a process for forming a storage electrode having a number of fine convexities formed on a surface thereof.

2. Description of Related Art

In a semiconductor memory such as a DRAM (dynamic random access memory), the elevation of the integration density is always demanded. Namely, the target is how to increase the capacitance per an occupying area. One means for achieving this target is a so called HSG (Hemi-Spherical-Grain) technology. This HSG technology is to form a number of fine convexities in the form of a mushroom or a hemi-sphere on a surface of a storage electrode so as to increase a surface area of the storage electrode thereby to increase a capacitance.

Referring to FIGS. 1A to 1C, there are shown diagrammatic sectional views for illustrating one example of a prior art process for forming a number of hemi-spherical grains on a surface of a storage electrode (capacitor lower plate).

As shown in FIG. 1A, a diffused layer 2 is formed in a silicon substrate 1, and an interlayer insulator film 3 formed of a silicon oxide is deposited on a surface of the silicon substrate 1 by use of a CVD (chemical vapor process) method. A contact hole is formed to penetrate through the interlayer insulator film 3 to reach the diffuse layer 2, and a phosphorus-doped amorphous silicon is deposited to fulfill the contact hole and to cover a surface of the interlayer insulator film 3, and then, is patterned to form a storage electrode 4 which is a capacitor lower plate of a stacked capacitor. The storage electrode 4 is electrically connected to the diffused layer 2 through the contact hole.

Thereafter, as shown in FIG. 1B, monosilane (SiH₄) is irradiated onto a surface of the storage electrode 4, and an annealing is carried out at the temperature of 560° C., so that migration of silicon atoms occurs at the surface of the storage electrode 4, with the result that a number of fine convexities in the form of a mushroom or a hemisphere are formed on the surface of the storage electrode 4. These fine convexities are called hemi-spherical grains (HSG), and are given with Reference Numeral 5.

Then, as shown in FIG. 1C, a capacitor dielectric film 7 is deposited on the surface of the storage electrode 4 by mean of the CVD process, and furthermore, a cell plate electrode 8 is formed on the capacitor dielectric film 7. Thus, a stacked capacitor is formed.

Here, focusing attention to the concentration of phosphorus (P) at the surface of the storage electrode 4, it is known that when the hemispherical grains 5 are formed by the migration of silicon atoms, the phosphorus in the proximity of the surface of the storage electrode 4 diffuses towards the inside of the storage electrode 4, so that the phosphorus concentration in the proximity of the surface of the storage electrode 4 becomes lower than that in the inside of the storage electrode 4. As a result, a depletion at the surface of the storage electrode 4 becomes large as a depletion layer 9 shown in an enlarged partially extracted view of the HSG in FIG. 1C. Because of this, even if the fine concavities-convexities are formed at the surface of the storage electrode 4, an advantage of the HSG cannot be sufficiently obtained.

In the prior art, for the purpose of overcoming this problem, the whole of the storage electrode 4 was annealed at a high temperature of 830° C. to 900° C. so as to cause the phosphorus concentrated in the inside of the storage electrode 4 to diffuse to a surface region of the storage electrode 4 again. For example, this annealing was conducted at 900° C. for 30 minutes. However, a current and future process trend is that a spacing between a source region and a drain region becomes short because of a fine patterning. Therefore, if a high temperature treatment is conducted, impurity of the source region and the drain region is diffused so that an effective spacing between the source region and the drain region becomes further short. Therefore, in order to ensure a desired spacing between the source region and the drain region, a low temperature process of 400° C. to 820° C. is becoming major, and as a matter of practice, it has become difficult to carry an annealing at as high temperature as 900° C.

However, it is difficult to cause the phosphorus concentrated in the inside of the storage electrode 4 to diffuse to the surface region of the storage electrode 4 by action of a low temperature treatment. For example, even if a heat treatment is conducted at 800° C. for 30 minutes, it is impossible to cause the phosphorus to diffuse to the surface.

Under the above mentioned circumstance, another approach has been proposed in which, first, a non-doped amorphous silicon storage electrode is formed and hemi-spherical grains are formed on a surface of the non-doped amorphous silicon storage electrode, and then, impurity is introduced into the storage electrode.

Referring to FIGS. 2A to 2C, there are shown diagrammatic sectional views for illustrating this second prior art storage electrode forming process of introducing the impurity into the storage electrode after the hemi-spherical grains formed on a surface of the storage electrode. In FIGS. 2A to 2C, elements corresponding to those shown in FIGS. 1A to 1C are given the same Reference Numerals.

A process shown in FIGS. 2A and 2B are similar to the process shown in FIGS. 1A and 1B, excepting that a non-doped amorphous silicon is deposited to form the storage electrode 4. After the hemi-spherical grains 5 are formed on a surface of the non-doped silicon storage electrode 4, phosphorus ions 6 are ion-implanted into the storage electrode 4 from a position above the hemi-spherical grains 5, as shown in FIG. 2C.

However, since the size of the hemi-spherical grains 5 is on the order of 0.1 μm, the hemi-spherical grains 5 are very fine and fragile. Therefore, if the phosphorus are simply ion-implanted in a conventional manner, the concavities-convexities easily disappear, with the result that the advantage of HSG can no longer be obtained.

As mentioned above, in the prior art there is no process for forming a storage electrode having a number of hemi-spherical grains formed on a surface thereof, by means of a low temperature process of 400° C. to 820° C.

### SUMMARY OF THE INVENTION

Accordingly, it is an object of the present invention to provide a process for forming a storage electrode, which has overcome the above mentioned problems of the prior art.

Another object of the present invention is to provide a process for forming a storage electrode having a number of fine convexities formed on a surface thereof and having a satisfactory impurity concentration, without extinguishing the fine convexities.

The above and other objects of the present invention are achieved in accordance with the present invention by a process for forming an electrode having a number of fine convexities formed on a surface thereof, wherein after a number of fine convexities are formed on a surface of an electrode, impurity is ion-implanted to the fine convexities under an ion implantation energy of 20 keV to 50 keV.

In an embodiment of the process in accordance with the present invention, the impurity is either phosphorus or arsenic. In addition, the impurity is ion-implanted at a dose of 5E15 cm⁻² to 5E16 cm⁻². However, when phosphorus is ion-implanted to the fine convexities, the ion implantation energy can be 20 keV to 60 keV.

Furthermore, the electrode is formed of amorphous silicon or polysilicon. Preferably, the electrode is formed of impurity-doped amorphous silicon or impurity-doped polysilicon.

In addition, the fine convexities are formed by a HSG technology. The electrode is a lower plate of a stacked capacitor or a floating gate.

With this arrangement, it is possible to introduce the impurity into the fine convexities formed on the surface of the electrode without extinguishing the fine convexities. Therefore, when the electrode is one plate of a capacitor, it is possible to easily obtain a necessary capacitance of the capacitor without a drop of the capacitance.

The above and other objects, features and advantages of the present invention will be apparent from the following description of preferred embodiments of the invention with reference to the accompanying drawings.

### BRIEF DESCRIPTION OF THE DRAWINGS

FIGS. 1A to 1C are diagrammatic sectional views for illustrating one example of a prior art process for forming a number of hemi-spherical grains on a surface of a storage electrode;

FIGS. 2A to 2C are diagrammatic sectional views for illustrating another example of a prior art process for forming a number of hemispherical grains on a surface of a storage electrode;

FIGS. 3A to 3D are diagrammatic sectional views for illustrating one embodiment of the process in accordance with the present invention for forming a number of hemi-spherical grains on a surface of a storage electrode;

FIG. 4 is a graph illustrating a bias dependency of the capacitance of a stacked capacitor; and

FIG. 5 is a graph illustrating a relation between the surface area of the storage electrode and the ion implantation energy.

### DESCRIPTION OF THE PREFERRED EMBODIMENTS

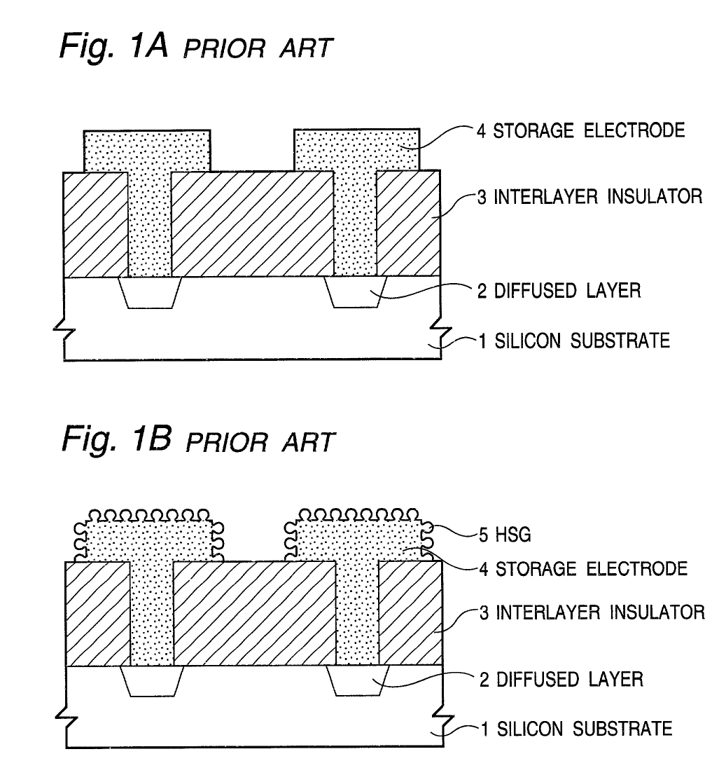

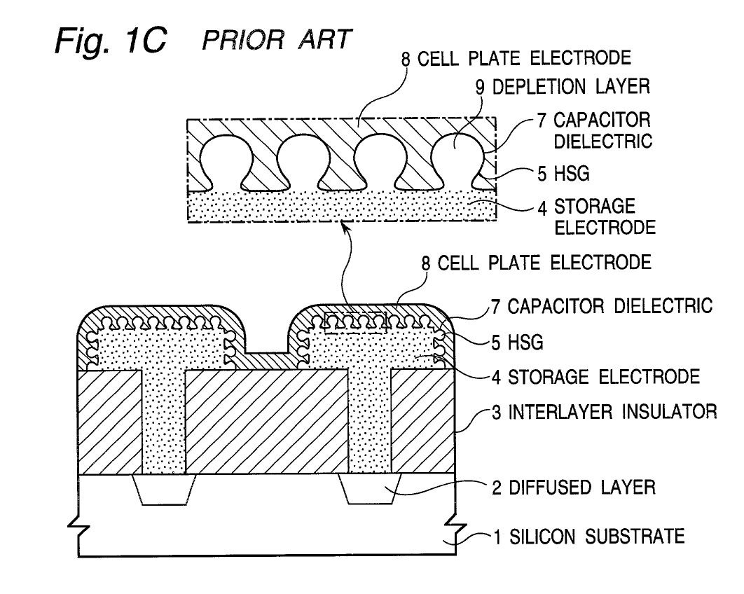

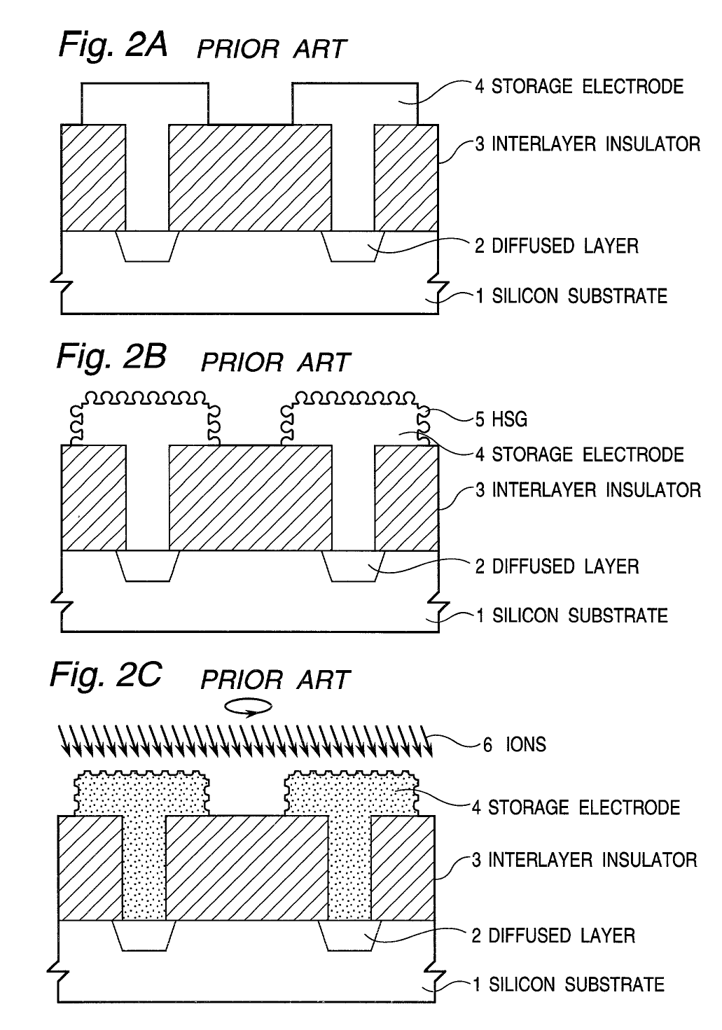

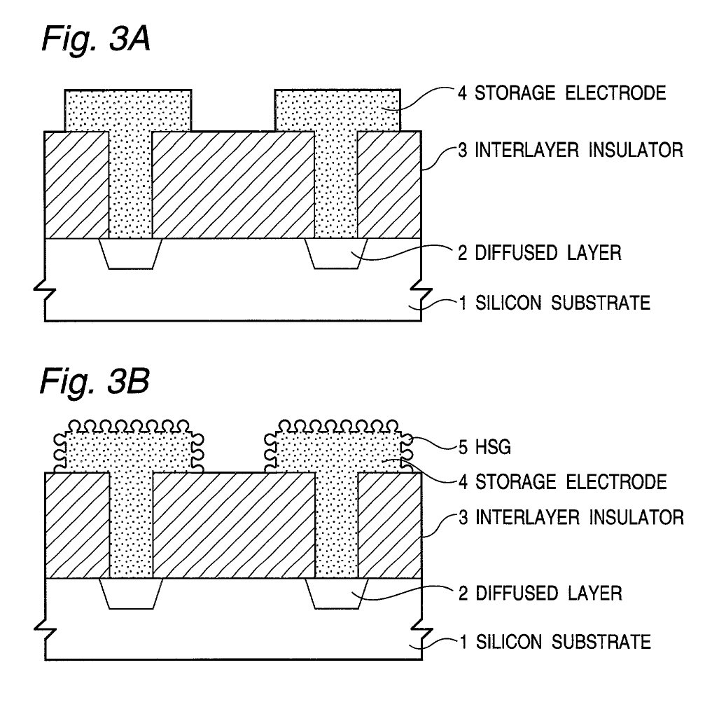

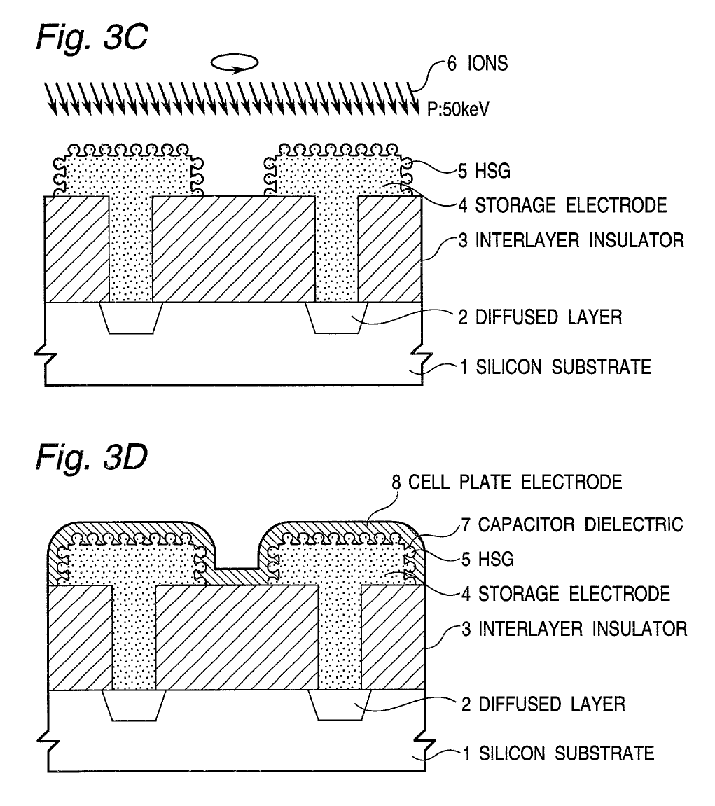

Referring to FIGS. 3A to 3D, there are shown diagrammatic sectional views for illustrating one embodiment of the process in accordance with the present invention for forming a number of hemispherical grains on a surface of a storage electrode. In FIGS. 3A to 3D, elements corresponding to those shown in FIGS. 1A to 1C are given the same Reference Numerals.

A process shown in FIGS. 3A and 3B are completely the same as the process shown in FIGS. 1A and 1B. After the hemi-spherical grains 5 are formed on a surface of the phosphorus-doped amorphous silicon (or polysilicon) storage electrode 4, phosphorus ions 6 are ion-implanted into the surface of the storage electrode 4 under the ion-implantation energy of 20 keV to 50 keV at a dose of 5E15 cm⁻² to 5E16 cm⁻², as shown in FIG. 3C.

This ion implantation is carried out toward a principal surface of the substrate 1 from a slant direction while rotating the substrate 1, so that the impurity can be effectively implanted to the hemi-spherical grains 5 formed on a side surface of the storage electrode 4 and to concave portions between the hemi-spherical grains 5.

Since it is no longer necessary to heat diffuse the impurity to the surface of the hemi-spherical grains 5 as in the prior art, it is not necessary to expose the semiconductor substrate to a high temperature of not lower than 830° C. As a result, it was confirmed that under this condition, the hemi-spherical grains 5 do not substantially disappear. The reason for this will be described in detail hereinafter.

Thereafter, as shown in FIG. 3D, a capacitor dielectric film 7 is formed on the surface of the storage electrode 4, and furthermore, a cell plate electrode 8 is formed on the capacitor dielectric film 7. Thus, a stacked capacitor of a DRAM is formed.

Now, why the hemi-spherical grains 5 do not substantially disappear in the present invention, will be described.

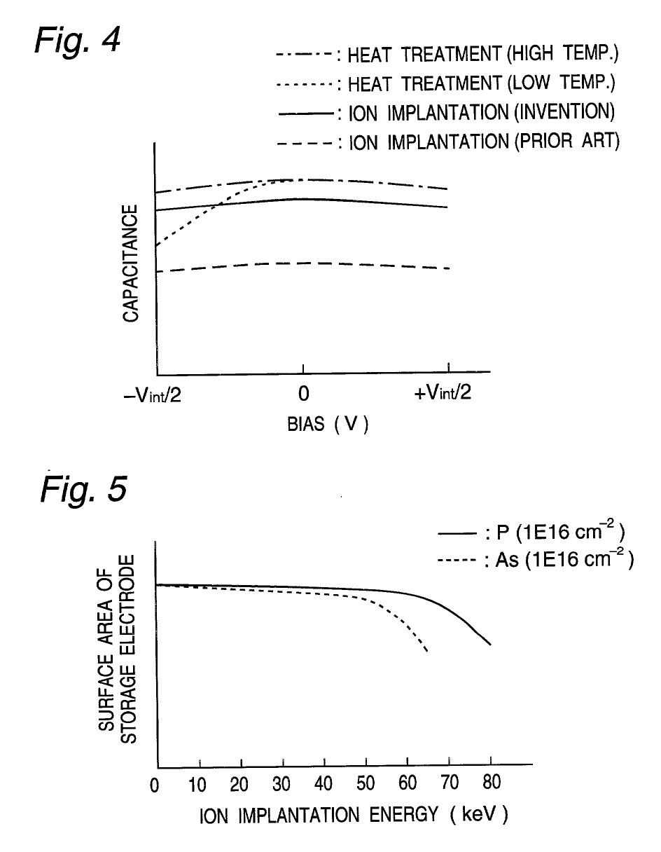

FIG. 4 is a graph illustrating a bias dependency of the capacitance of a stacked capacitor, and shows four examples, namely, a first example that ions are simply implanted into the storage electrode in accordance with the prior art, a second example that the storage electrode is heat-treated at a high temperature, a third example that the storage electrode is heat-treated at a low temperature, and a fourth example that ions are implanted into the storage electrode in accordance with the present invention.

The capacitance was measured by fixing the capacitor lower plate, namely, the storage electrode 4 to the ground potential, and by applying a voltage of −Vint/2 to +Vint/2 to the capacitor upper plate, namely, the cell plate 8, where Vint/2 is equal to a power supply voltage and on the order of 1.5V to 5V. In an actual use, however, a fixed bias voltage equal to ½ of the power supply voltage is applied to the capacitor upper plate, and either 0V or a voltage near to the power supply voltage is applied to the capacitor lower plate as memory information. The reason for this is that: if the capacitor upper plate is fixed to ½ of the power supply voltage, the breakdown of the capacitor dielectric film can be surely prevented and the bias voltage can be lowered, in comparison with the case that the capacitor upper plate is fixed to either 0V or the power supply voltage.

As seen from FIG. 4, when the ions are simply implanted into the storage electrode in accordance with the prior art, the bias dependency of the capacitance is small, but since the concavities-convexities of the hemi-spherical grains disappear, the capacitance is small. Namely, the advantage of the hemi-spherical grains cannot be obtained.

On the other hand, when the storage electrode is heat-treated at a high temperature, the capacitance is high over the whole of the bias voltage range and when the storage electrode is heat-treated at a low temperature, the capacitance becomes small at the bias voltage of −Vint/2. The reason for this is as follows:

When the storage electrode is heat-treated at a low temperature, since the impurity concentration is insufficient, the depletion layer is apt to easily extend. Therefore, when a bias voltage is applied to the capacitor, the capacitance drops. As a result, when information of a high level is stored, the capacitance is smaller than that when information of a low level is stored, so that a hold time of the stored information becomes short. Namely, a necessary hold characteristics cannot be satisfied, so that a disappearance of data is easy to occur.

If the storage electrode is heat-treated at a high temperature, impurity diffuses into the whole of the hemi-spherical grains. Therefore, even if a bias voltage is applied to the capacitor, the depletion layer is hardly to occur. Accordingly, the capacitance does not drop, independently of which of the high level and the low level is the stored information. Namely, a good hold characteristics can be obtained. Therefore, from the viewpoint of only the capacitance, the high temperature heat-treatment is the most excellent. However, as mentioned hereinbefore, the high temperature heat-treatment cannot be applied to the low temperature process which is the current and future process trend.

When ions are implanted into the storage electrode under the ion implantation energy of 20 keV to 50 keV at the dose of 5E15 cm⁻² to 5E16 cm⁻², preferably, when phosphorus is ion-implanted at the dose of 1E16 cm⁻², the hemi-spherical grains having less bias dependency of the capacitance could be obtained as shown in the graph of FIG. 4. Namely, since the capacitance does not drop independently of which of the high level and the low level is the stored information, a good hold characteristics can be obtained.

Here, the higher the impurity concentration is, it is preferable. However, in order to elevate the impurity concentration, the time of the ion implantation becomes long. Therefore, it is actually sufficient if the dose is in the range of 5E15 cm⁻² to 5E16 cm⁻².

Referring to FIG. 5, there is shown a graph illustrating a relation between the surface area of the storage electrode and the ion implantation energy. As seen from FIG. 5, when the dose of the phosphorus is fixed to 1E16 cm⁻², the surface area of the storage electrode is substantially at a constant until the ion implantation energy reaches 60 keV, and abruptly becomes small after the ion implantation energy exceeds 60 keV. On the other hand, when arsenic (As) is ion-implanted into the HSG storage electrode with the fixed dose of 1E16 cm⁻², the surface area of the storage electrode can be said to be substantially at a constant, although the surface area actually becomes slightly small, until the ion implantation energy reaches 50 keV, and abruptly becomes small after the ion implantation energy exceeds 50 keV.

Totally considering the above mentioned factors, if phosphorus or arsenic is ion-implanted into the HSG storage electrode under the ion implantation energy of 20 keV to 50 keV when the dose is 1E16 cm⁻², the hemi-spherical grains do not disappear.

The embodiment for forming the storage electrode of the stacked capacitor of the DRAM has been thus described. However, it would be a matter of course to persons skilled in the art that the present invention can be effectively applied for forming a floating gate of an EEPROM (electrically erasable programmable read only memory).

As seen from the above, according to the present invention, since it is possible to introduce the impurity into the hemi-spherical grains of the storage electrode without extinguishing the fine convexities realized by the hemi-spherical grains, it is possible to easily obtain a necessary capacitance of the capacitor without a drop of the capacitance.

The invention has thus been shown and described with reference to the specific embodiments. However, it should be noted that the present invention is in no way limited to the details of the illustrated structures but changes and modifications may be made within the scope of the appended claims.

1. A process for forming an electrode having a number of fine convexities formed on a surface thereof, wherein after a number of fine convexities are formed on a surface of an electrode, impurity is ion-implanted to said fine convexities under an ion implantation energy of 20 keV to 50 keV.

2. A process claimed in claim 1 wherein said impurity is either phosphorus or arsenic.

3. A process claimed in claim 2 wherein said impurity is ion-implanted at a dose of 5E15 cm⁻² to 5E16 cm⁻².

4. A process claimed in claim 3 wherein said electrode is formed of amorphous silicon or polysilicon.

5. A process claimed in claim 3 wherein said electrode is formed of impurity-doped amorphous silicon or impurity-doped polysilicon.

6. A process claimed in claim 3 wherein said fine convexities are formed by a HSG technology.

7. A process claimed in claim 3 wherein said electrode is a lower plate of a stacked capacitor.

8. A process claimed in claim 3 wherein said electrode is a floating gate.

9. A process claimed in claim 2 wherein said electrode is formed of amorphous silicon or polysilicon.

10. A process claimed in claim 2 wherein said electrode is formed of impurity-doped amorphous silicon or impurity-doped polysilicon.

11. A process claimed in claim 2 wherein said fine convexities are formed by a HSG technology.

12. A process claimed in claim 2 wherein said electrode is a lower plate of a stacked capacitor.

13. A process for forming an electrode having a number of fine convexities formed on a surface thereof, wherein after a number of fine convexities are formed on a surface of an electrode, phosphorus is ion-implanted to said fine convexities under an ion implantation energy of 20 keV to 60 keV.

14. A process claimed in claim 13 wherein said impurity is ion-implanted at a dose of 5E15 cm⁻² to 5E16 cm⁻².

15. A process claimed in claim 14 wherein said electrode is formed of amorphous silicon or polysilicon.

16. A process claimed in claim 14 wherein said electrode is formed of impurity-doped amorphous silicon or impurity-doped polysilicon.

17. A process claimed in claim 14 wherein said fine convexities are formed by a HSG technology.

18. A process claimed in claim 14 wherein said electrode is a lower plate of a stacked capacitor.

19. A process claimed in claim 14 wherein said electrode is a floating gate.

20. A process claimed in claim 13 wherein said electrode is formed of impurity-doped amorphous silicon or impurity-doped polysilicon, and said fine convexities are formed by a HSG technology.
